(19) United States
(12) Patent Application Publication
(10) Pub. No.: US 2019/0017816 A1
(43) Pub. Date: Jan. 17, 2019

(54) HEIGHT MEASUREMENT APPARATUS

(71) Applicant: ASML NETHERLANDS B.V., Veldhoven (NL)

(72) Inventors: Antonius Johannes Maria NELLISSEN, Horst (NL); Jacob Roger HAARTSEN, Eindhoven (NL); Krassimir Todorov KRASTEV, Eindhoven (NL)

(21) Appl. No.: 16/061,471

(22) PCT Filed: Nov. 28, 2016
(86) PCT No.: PCT/EP2016/078930

§ 371 Date: Jun. 12, 2018

(30) Foreign Application Priority Data
Dec. 21, 2015 (EP) 15201737.2

(51) Int. Cl. G01B 13/22; G03F 7/20

(52) U.S. Cl. CPC G01B 13/22; G03F 7/70625; G03F 7/70191

(57) ABSTRACT

A height measurement apparatus comprising an array of differential pressure sensors, each differential pressure sensor comprising a reference outlet and a measurement outlet, the reference outlet being a predetermined distance from a reference surface, and each differential pressure sensor further comprising an inlet configured to provide pressurized gas for the reference outlet and the measurement outlet. A flexible membrane is positioned such that a reference side of the flexible membrane is in fluid communication with the reference outlet and a measurement side of the flexible membrane is in fluid communication with the measurement outlet. The flexible membrane is configured to move when a pressure change occurs at the measurement outlet and a detector is configured to monitor the movement of the flexible membrane.

### CROSS-REFERENCE TO RELATED APPLICATIONS

This application claims priority of EP application 15201737.2 which was filed on 21 Dec. 2015 and which is incorporated herein in its entirety by reference.

### FIELD

The present invention relates to a height measurement apparatus and method. The height measurement apparatus may form part of a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate (e.g. a silicon wafer).

Before a pattern is projected from a patterning device onto a layer of radiation sensitive material provided on a substrate the height of the substrate is measured. In order to achieve this, the lithographic apparatus is provided with a height measurement apparatus. The height measurement apparatus measures the height of the substrate across a surface of the substrate. The substrate height measurements are used to form a substrate height map which assists accurate projection of a pattern onto the substrate. It may be desirable to provide, for example, a height measurement apparatus which obviates or mitigates one or more of the problems of the prior art, whether identified herein or elsewhere.

### SUMMARY

According to a first aspect of the invention there is provided a height measurement apparatus comprising an array of differential pressure sensors, each differential pressure sensor comprising a reference outlet and a measurement outlet, the reference outlet being a predetermined distance from a reference surface, an inlet configured to provide pressurized gas for the reference outlet and the measurement outlet, a flexible membrane positioned such that a reference side of the flexible membrane is in fluid communication with the reference outlet and a measurement side of the flexible membrane is in fluid communication with the measurement outlet. The flexible membrane is configured to move when a pressure change occurs at the measurement outlet. A detector is configured to monitor the movement of the flexible membrane.

Using an array of differential pressure sensors to measure the height of a substrate takes less time than using a single differential pressure sensor. An array of differential pressure sensors can measure the height of a substrate across a greater surface area of the substrate than a single differential pressure sensor.

A reference channel and a measurement channel may be provided, the reference channel being configured to provide fluid communication between the inlet and the reference side of the flexible membrane, and the measurement channel being configured to provide fluid communication between the inlet and the measurement side of the flexible membrane.

The reference channel and the measurement channel may be configured to act as flow restrictors.

Flow restrictors typically act to control and/or smooth a mass flow of pressurized gas through the reference channel and the measurement channel. It is beneficial to have a smooth flow of pressurized gas rather than a turbulent flow as a turbulent flow may cause the flexible membrane to move without a height change at the substrate occurring.

A spacing between adjacent differential pressure sensors in the array may be 3 mm or less.

The detector may comprise a detection device provided on the flexible membrane.

The detection device may comprise at least one piezo-resistive element.

The detection device may comprise at least one piezo-resistive element configured to be a measurement element and at least one piezo-resistive element configured to be a reference element.

The measurement element may be used to provide substrate height measurements and reference element may be used to provide reference measurements. An output signal of a reference element may be deducted from an output signal of a measurement element in order to remove background noise such as, for example, thermal noise from substrate height measurements.

The flexible membrane may be of a shape that comprises at least three vertices.

Having a non-circular flexible membrane may be preferable in some circumstances as some regions on a non-circular flexible membrane may move and/or distort more than other regions (for a given general movement of the flexible membrane). These regions provide a greater sensitivity to the movement of the flexible membrane and may therefore be used to provide substrate height measurements with increased resolution.

The flexible membrane may be substantially circular. Two piezo-resistive elements may be configured such that they are substantially parallel with a radius of the flexible membrane, and two piezo-resistive elements may be configured such that they are substantially perpendicular with the radius of the flexible membrane.

The radius of a circular flexible membrane will increase when the flexible membrane moves. The orientation of piezo-resistive elements relative to the radius of the circular flexible membrane may be selected in order to achieve a desired change in resistance when the flexible membrane moves. This enables the sensitivity of the differential pressure sensor to be selected as desired.

The four piezo-resistive elements may be arranged in a Wheatstone bridge circuit.

Arranging the piezo-resistive elements in a Wheatstone bridge circuit allows the effects of temperature on an output signal of the piezo-resistive elements of the Wheatstone bridge circuit to be compensated for. This means that the background noise present in substrate height measurements may be reduced.

The detection device may comprise a flexible electrode.

The detector may further comprise a static perforated electrode provided opposite the flexible electrode such that the flexible electrode and the static perforated electrode form a capacitor.

The detector may further comprise a second flexible electrode provided on a second flexible membrane, the second flexible membrane being provided opposite the flexible membrane such that the flexible electrodes form a capacitor.

An advantage of a capacitor based differential pressure sensor compared with a piezo-resistive based differential pressure sensor is the insignificant impact of thermal noise on pressure measurements made using a capacitor based differential pressure sensor. A capacitor based differential pressure sensor does not draw a significant electrical current and therefore does not suffer from thermal noise arising from heat generated by a significant electrical current flowing through a resistor.

The detection device may comprise a flexible optical resonator.

A waveguide may be provided on the flexible membrane, the waveguide being configured to provide broadband radiation to the flexible optical resonator.

The flexible membrane may be substantially circular and the flexible optical resonator may be a flexible optical ring resonator.

At least two of the flexible membranes of the array of differential pressure sensors may be provided with flexible optical resonators, and the flexible optical resonators may have different lengths.

Having flexible optical resonators with different lengths may be advantageous as each flexible optical resonator may have a unique range of possible resonant frequencies. Providing each flexible optical resonator in the array with a different length allows for an output signal of every differential pressure sensor in the array to be analysed using a single optical spectrum analyser rather than requiring multiple optical spectrum analysers.

The detector may further comprise a broadband radiation source configured to provide radiation having wavelengths in the range 500-2000 nm to the waveguide.

The detector may further comprise an optical spectrum analyser configured to receive radiation from the waveguide.

The detection device may comprise a reflective portion configured to reflect incident radiation towards a photodetector.

The detector may further comprise a beam splitter configured to split an incident beam of radiation into a first beam and a second beam, the first beam being directed to the photodetector and a second beam being directed to the reflective portion.

The detection device may comprise a Mach-Zehnder interferometer.

The height measurement apparatus may further comprise a processor configured to receive an output signal from the detector and use the signal to determine a height of a substrate located proximate the measurement outlet.

The array may be fabricated from a substrate stack.

Forming the array of differential pressure sensors from a single substrate stack, may be beneficial as the differential pressure sensors fabricated using the same substrates may have substantially identical characteristics such as, for example, measurement channel lengths.

The substrate stack may comprise a plurality of semiconductor wafers.

The height measurement apparatus may further comprise a reference sensor, the reference sensor comprising a reference outlet and a measurement outlet, the reference outlet being a predetermined distance from a reference surface; a flexible membrane positioned such that a reference side of the flexible membrane is in fluid communication with the reference outlet and a measurement side of the flexible membrane is in fluid communication with the measurement outlet; and a detector configured to monitor the movement of the flexible membrane; wherein the reference sensor does not include an inlet configured to provide pressurized gas for the reference outlet and the measurement outlet.

Having a reference sensor may be advantageous as an output signal of the reference sensor may be independent of substrate height changes. The reference sensor may provide an output signal that is indicative of background noise present in substrate height measurements. The output signal of the reference sensor may be deducted from the output signals of other differential pressure sensors in the array in order to remove background noise from the substrate height measurements made by the array.

According to a second aspect of the invention there is provided a lithographic apparatus comprising an illumination system configured to condition a radiation beam; a support constructed to support a patterning device, the patterning device being capable of imparting the radiation beam with a pattern in its cross-section to form a patterned radiation beam; a substrate table constructed to hold a substrate; and a projection system configured to project the patterned radiation beam onto a target portion of the substrate; wherein the lithographic apparatus further comprises a height measurement apparatus comprising an array of differential pressure sensors, each differential pressure sensor comprising a reference outlet and a measurement outlet, the reference outlet being a predetermined distance from a reference surface; an inlet configured to provide pressurized gas for the reference outlet and the measurement outlet; a flexible membrane positioned such that a reference side of the flexible membrane is in fluid communication with the reference outlet and a measurement side of the flexible membrane is in fluid communication with the measurement outlet, the flexible membrane being configured to move when a pressure change occurs at the measurement outlet; and a detector configured to monitor the movement of the flexible membrane.

According to a third aspect described here, there is provided a height measurement method comprising providing an array of differential pressure sensors with a pressurized gas, each differential pressure sensor comprising a flexible membrane configured to move when a pressure change occurs at a measurement outlet of the differential pressure sensor; positioning a surface of a substrate proximate measurement outlets of the array of differential pressure sensors; providing relative movement between the array of differential pressure sensors and the surface of the substrate; sensing pressure changes during the movement by monitoring movement of the flexible membrane; and analysing the sensed pressure changes to determine the height of the substrate.

According to a fourth aspect described herein, there is provided a process of manufacturing a height measurement apparatus, the process comprising providing a detection device on a device layer of a first wafer; providing a second wafer with an inlet, a reference channel and a reference outlet, the inlet, reference channel and reference outlet being in fluid communication with each other; bonding the first wafer to the second wafer such that a continuous path exists from the inlet, through the reference channel, past the detection device and through the reference outlet; thinning the first wafer from underneath the first wafer; forming a flexible membrane from the first wafer such that the detection device is located on the flexible membrane; providing a third wafer with a measurement outlet; bonding the third wafer to the first wafer such that a measurement channel is defined by the third wafer and the first wafer, the measurement channel being in fluid communication with the inlet and the measurement outlet such that a continuous path exists from the inlet, through the measurement channel, past the flexible membrane and through the measurement outlet; providing a fourth wafer with an inlet and a reference outlet channel; and bonding the fourth wafer to the second wafer such that the inlet of the fourth wafer is aligned with the inlet of the second wafer, and the reference outlet channel is in fluid communication with the reference outlet.

The second wafer may be provided with a device chamber configured to accommodate monitoring electronics and/or optics.

Features of different aspects of the invention may be combined with features of other aspects of the invention.

### BRIEF DESCRIPTION OF THE DRAWINGS

Embodiments of the invention will now be described, by way of example only, with reference to the accompanying schematic drawings, in which:

FIG. 1 schematically depicts a lithographic apparatus comprising a height measurement apparatus according to an embodiment of the invention;

FIG. 2 schematically depicts a height measurement apparatus according to an embodiment of the invention;

FIG. 3 is a schematic depiction from above and in cross-section of a height measurement apparatus according to an alternative embodiment of the invention;

FIG. 4 is a schematic depiction from above and in cross-section of a height measurement apparatus according to an alternative embodiment of the invention;

FIG. 5 is a schematic depiction of a rotated view from above and in cross-section of the height measurement apparatus depicted in FIG. 4;

FIG. 6 is a schematic depiction from above and in cross-section of a height measurement apparatus according to an alternative embodiment of the invention;

FIG. 7 is a schematic depiction from above and in cross-section of a height measurement apparatus comprising an array of differential pressure sensors according to an embodiment of the invention;

FIG. 8 is a schematic depiction from above and in cross-section of a height measurement apparatus according to an alternative embodiment of the invention;

FIG. 9 is a schematic depiction from above and in cross-section of a height measurement apparatus comprising an array of differential pressure sensors according to an alternative embodiment;

FIG. 10 is a schematic depiction of a differential pressure sensor according to an embodiment of the invention; and

FIG. 11 is a schematic depiction of a method of manufacturing a height measurement apparatus according to an embodiment of the invention;

### DETAILED DESCRIPTION

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

A support structure holds the patterning device. It holds the patterning device in a way that depends on the orientation of the patterning device, the design of the lithographic apparatus, and other conditions, such as, for example, whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “projection lens” herein may be considered as synonymous with the more general term “projection system”.

The term “illumination system” used herein may encompass various types of optical components, including refractive, reflective, and catadioptric optical components for directing, shaping, or controlling the beam of radiation, and such components may also be referred to below, collectively or singularly, as a “lens”.

The lithographic apparatus may also be of a type wherein the substrate is immersed in a liquid having a relatively high refractive index, e.g. water, so as to fill a space between the final element of the projection system and the substrate. Immersion techniques are well known in the art for increasing the numerical aperture of projection systems.

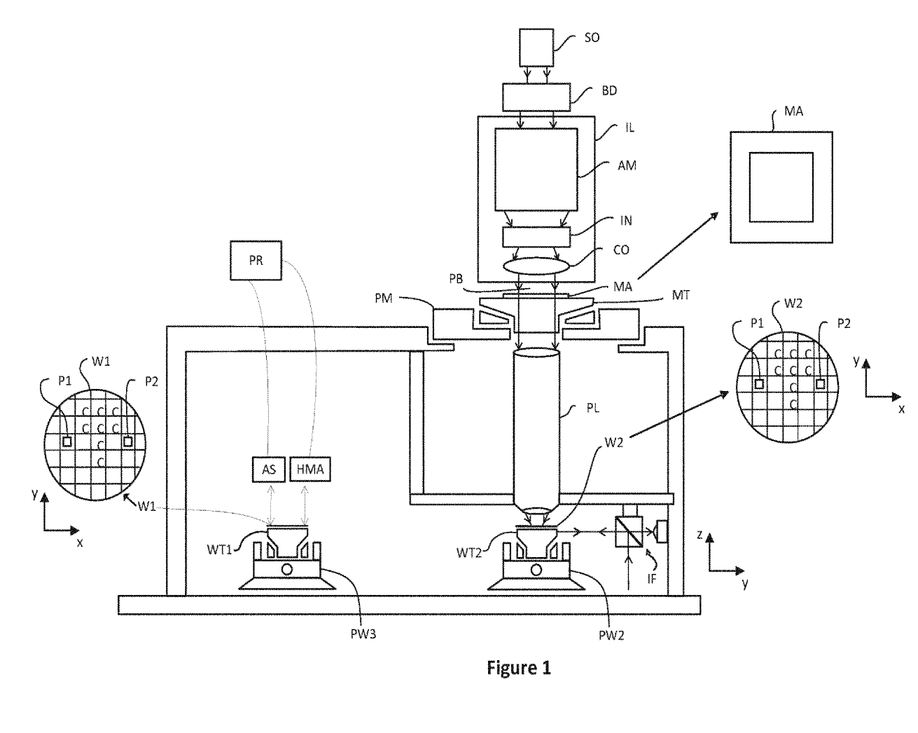

FIG. 1 schematically depicts a lithographic apparatus comprising a height measurement apparatus HMA according to an embodiment of the invention. The apparatus comprises:
a. an illumination system IL to condition a beam PB of radiation (e.g. deep ultraviolet radiation or extreme ultraviolet radiation).
b. a support structure (which may be referred to as a mask table) MT to support a patterning device (e.g. a mask) MA and connected to first positioning device PM to accurately position the patterning device with respect to item PL;
c. a substrate table (which may be referred to as a wafer table) WT2 for holding a substrate (e.g. a resist coated wafer) W2 and connected to second positioning device PW2 for accurately positioning the substrate with respect to item PL;
d. another substrate table WT1 for holding a substrate W1 and connected to third positioning device PW3 for accurately positioning the substrate with respect to alignment system AS, and a height measurement apparatus HMA for accurately measuring the height of the substrate; and
e. a projection system (e.g. a refractive projection lens) PL configured to image a pattern imparted to the radiation beam PB by patterning device MA onto a target portion C (e.g. comprising one or more dies) of the substrate W2.

As here depicted, the apparatus is of a transmissive type (e.g. employing a transmissive mask). Alternatively, the apparatus may be of a reflective type (e.g. employing a programmable mirror array of a type as referred to above).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. The source SO and the illuminator IL, together with the beam delivery system BD if required, may be referred to as a radiation system.

The illuminator IL may comprise adjusting means AM for adjusting the angular intensity distribution of the beam. Generally, at least the outer and/or inner radial extent of the intensity distribution in a pupil plane of the illuminator can be adjusted. In addition, the illuminator IL generally comprises various other components, such as an integrator IN and a condenser CO. The illuminator provides a conditioned beam of radiation PB, having a desired uniformity and intensity distribution in its cross section.

The radiation beam PB is incident on the patterning device (e.g. mask) MA, which is held on the support structure MT. Having traversed the patterning device MA, the beam PB passes through the lens PL, which focuses the beam onto a target portion C of the substrate W2. With the aid of the second positioning device PW2 and position sensor IF (e.g. an interferometric device), the substrate table WT2 can be moved accurately, e.g. so as to position different target portions C in the path of the beam PB. Similarly, the first positioning device PM and another position sensor (which is not explicitly depicted in FIG. 1) can be used to accurately position the patterning device MA with respect to the path of the beam PB, e.g. after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner) the support structure MT may be connected to a short stroke actuator only, or may be fixed.

The lithographic apparatus may for example move the patterning device MA and the substrate W2 with a scanning motion when projecting the pattern from the patterning device onto a target portion C. Cartesian coordinates are indicated in FIG. 1. As is conventional, the z-direction corresponds with an optical axis of the radiation beam PB. In an embodiment in which the lithographic apparatus is a scanning lithographic apparatus, the y-direction corresponds with the direction of scanning motion.

As depicted, the lithographic apparatus may be of a type having two (dual stage) or more substrate tables WT1, WT2. In a dual stage lithographic apparatus two substrate tables WT1, WT2 are provided in order to allow properties of one substrate W1 to be measured whilst exposure of another substrate W2 is taking place (“exposure of a substrate” means projection of patterned radiation onto the substrate as described above).

In the dual stage lithographic apparatus depicted in FIG. 1 an alignment system AS is provided on the left-hand side of the figure. A height measurement apparatus HMA is also provided on the left-hand side of FIG. 1. The projection system PL is provided on the right-hand side of FIG. 1. The alignment system AS measures the positions of alignment marks provided on a substrate W1 (schematically depicted by boxes P1, P2) which is held on a first substrate table WT1. The height measurement apparatus measures the height of the substrate W1. A pattern is simultaneously projected by the projection system PL onto a substrate W2 held on a second substrate table WT2. When measurement of the substrate W1 supported by the first substrate table WT1 is completed and exposure of the substrate W2 supported by the second substrate table WT2 is completed, the positions of the substrate tables are swapped over. The substrate W1 supported by the first substrate table WT1 is then exposed using patterned radiation projected by the projection system PL. The already exposed wafer W2 supported by the second substrate table WT2 is removed from the substrate table for subsequent processing. Another substrate is then placed on the second substrate table WT2 for measurement by the alignment system AS and the height measurement apparatus prior to exposure using patterned radiation projected by the projection system PL.

An interferometer (not depicted) and/or other position measurement means may be used to monitor the position of the substrate table WT1 during alignment and height measurements. A processor PR may receive data from the alignment system AS, the height measurement apparatus HMA and also receive substrate table WT1 position information. Since the substrate W is fixed on the substrate table WT1, position information relating to the substrate table may be taken as being position information relating to the substrate.

The flatness of the substrate is an important factor in accurately projecting an image onto the substrate during a lithographic exposure. Focus errors are introduced when the substrate is not flat. In general, the less flat a substrate is then the greater the focus errors are. Measuring the height, and therefore the flatness, of a substrate before carrying out a lithographic exposure with that substrate allows for focus errors to be determined and corrected for.

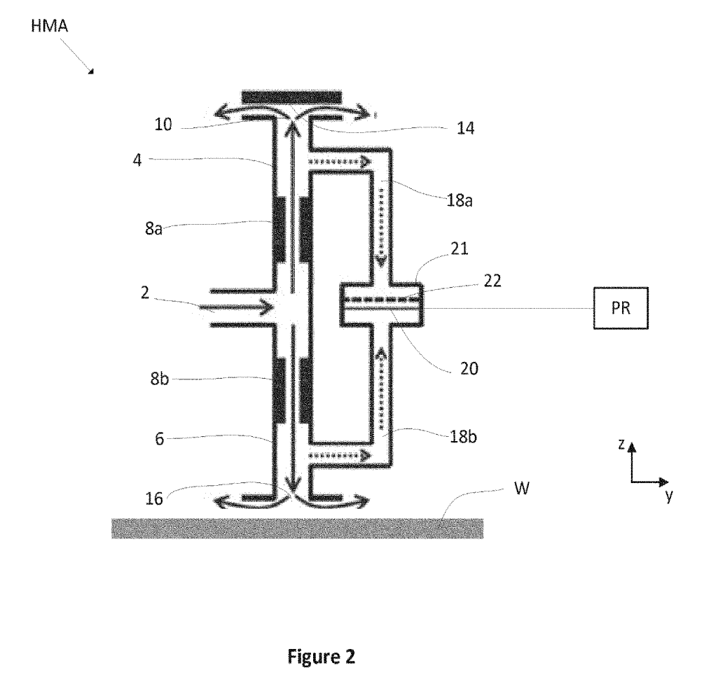

FIG. 2 is a schematic depiction of a height measurement apparatus according to an embodiment of the invention, the height measurement apparatus comprising a single differential pressure sensor. The arrows depicted in FIG. 2 show the direction of pressurized gas flow through the height measurement apparatus. Pressurized gas is provided to the height measurement apparatus through an inlet 2. The pressurized gas is then split between a reference channel 4 and a measurement channel 6. Flow restrictors 8a, 8b are provided in the reference channel 4 and the measurement channel 6. Flow restrictors act to control and/or steady a mass flow of pressurized gas through the reference channel 4 and the measurement channel 6. The flow restrictors 8a, 8b may restrict the mass flow of pressurized gas through the reference channel 4 and the measurement channel 6 equally. The resting position of the flexible membrane 20 may be defined as the position of the flexible membrane when the distance from a measurement outlet 16 to a substrate W is equal to the distance from a reference outlet 10 to a reference surface 14. Restricting the mass flow of pressurized gas equally through the reference channel 4 and the measurement channel 6 allows a flexible membrane 20 to be flat in its resting position, i.e. not significantly distorted. If the flexible membrane 20 is already distorted in its resting position then movement of the flexible membrane is restricted in one direction relative to the other. Having the flexible membrane 20 in a flat resting position may be preferred because it permits a larger range of movement of the flexible membrane. However, this is not essential to the invention.

Once past the flow restrictor 8a in the reference channel 4, the pressurized gas is split between the reference outlet 10 and the flexible membrane 20. In the embodiment depicted by FIG. 2, the flexible membrane 20 is located within a membrane chamber 21. A connecting channel 18a provides a fluid communication between the reference channel 4 and the flexible membrane 20. The reference outlet 10 is a predetermined distance from a reference surface 14. The reference surface 14 may be at least 1 micron from the reference outlet 10. The reference surface 14 may be up to 500 microns from the reference outlet 10. The reference surface 14 may, for example, be approximately 100 microns from the reference outlet 10.

Once past the flow restrictor 8b in the measurement channel 6, the pressurized gas is split between the measurement outlet 16 and the flexible membrane 20. A connecting channel 18b provides fluid communication between the measurement channel 6 and the flexible membrane 20. The measurement outlet 16 is an unknown distance from the substrate W.

The range of movement of the flexible membrane 20 may depend on the surface area of the flexible membrane. The connecting channels 18a, 18b may connect to a measurement chamber 21. The measurement chamber 21 is configured to accommodate a flexible membrane 20 with a sufficient surface area for precise differential pressure measurements to be made. In some embodiments the connecting channels 18a, 18b are not present. Examples of such embodiments are described further below.

The flexible membrane 20 comprises a reference side that is in fluid communication with the reference outlet 10 and a measurement side that is in fluid communication with the measurement outlet 16. The flexible membrane 20 may take any desired shape. For example, the flexible membrane 20 may be substantially circular. Alternatively, the flexible membrane 20 may be polygonal, e.g. rectangular. The flexible membrane 20 may have at least three vertices. The surface area of the flexible membrane 20 affects the sensitivity of the differential pressure sensor comprising the flexible membrane. The larger the surface area of the flexible membrane 20 is, the more sensitive the differential pressure sensor is to pressure changes. The surface area of the flexible membrane 20 may therefore be selected to provide an appropriate sensitivity for a given height measurement. The flexible membrane 20 may be circular with a diameter of between 1.0-2.5 mm such as, for example 1.5 mm. The thickness of the flexible membrane 20 affects how sensitive the differential pressure sensor is. The thinner the flexible membrane 20 is the more sensitive the differential pressure sensor is to pressure changes. The flexible membrane 20 may, for example, have a thickness of approximately 5 μm.

In the embodiment of FIG. 2 a static perforated electrode 22 is provided opposite the flexible membrane 20. The flexible membrane 20 comprises a flexible electrode such that, in the embodiment of FIG. 2, the flexible electrode and the static perforated electrode 22 form a capacitor. The flexible electrode may be considered to be an example of a detection device. The flexible electrode may be a layer of metal deposited on the flexible membrane 20. The flexible electrode may, for example, be formed from Aluminium, Gold, Platinum, Chromium or Titanium. The flexible membrane 20 may be provided with the flexible electrode via known metal deposition techniques such as, for example, metal evaporation or sputtering. The static perforated electrode 22 is perforated to allow fluid communication between the reference side of the flexible membrane 20 and the reference outlet 10.

During use the measurement outlet 16 of the height measurement apparatus is located proximate a surface of a substrate W. The substrate W may be scanned beneath the measurement outlet of the height measurement apparatus and/or the measurement outlet 16 of the height measurement apparatus may be scanned across a substrate W. The z position of the height measurement apparatus may be fixed at a predetermined value during use. As the height of the substrate W with respect to the measurement outlet 16 changes during the scanning, the distance between the measurement outlet and the substrate changes. If the distance between the substrate W and the measurement outlet 16 decreases this will cause an increase of pressure at the measurement outlet as the flow of pressurized gas experiences greater restriction on exiting the measurement outlet. If the distance between the substrate

W and the measurement outlet 16 increases this will cause a decrease of pressure at the measurement outlet as the flow of pressurized gas experiences less restriction on exiting the measurement outlet.

Pressure changes at the measurement outlet 16 are communicated via the connecting channel 18b to the flexible membrane. These pressure changes cause the flexible membrane 20 to move. The flexibility of the flexible membrane 20 is such that a pressure change at the measurement outlet 16 results in movement of the flexible membrane 20. A detector is provided to monitor the movement of the flexible membrane 20. In the embodiment of FIG. 2, the detector comprises the capacitor formed from the flexible electrode and the static perforated electrode 22. Other detectors may be used. When the pressure changes at the measurement outlet 16 the flexible membrane 20 moves. As the flexible membrane 20 moves the separation between the flexible electrode and the static perforated electrode 22 changes. Changing the separation between the flexible electrode and the static perforated electrode 22 changes the capacitance of the capacitor formed from the flexible electrode and the static perforated electrode. A processor PR may be provided, the processor being configured to receive an output signal and use that signal to determine the distance between the measurement outlet 16 and the substrate W. Monitoring electronics (not shown) may be provided, the monitoring electronics being configured to apply a potential across the capacitor and provide an output signal indicative of the capacitance of the capacitor to the processor PR. For example, the monitoring electronics 30 may produce an output signal in the form of a variable voltage that is indicative of the capacitance of the capacitor.

The faster the differential pressure sensor responds to substrate height changes, the faster the height measurement apparatus comprising the differential pressure sensor may be scanned across a substrate during a height measurement. The speed at which the differential pressure sensor responds to substrate height changes is at least in part determined by the volume of the height measurement apparatus through which pressurized gas flows. A differential pressure sensor that responds quickly to substrate height changes may be achieved by reducing the volume through which pressurized gas flows through the differential pressure sensor. The volume through which pressurized gas flows may comprise the volume defined by the length, width and depth of the reference channel 4 from the inlet 2 to the reference outlet 10, the length, width and depth of the measurement channel 6 from the inlet 2 to the measurement outlet 16, the length, width and depth of connecting channels 18a, 18b and, if circular, the diameter and depth of the measurement chamber 21. For example, the width of the reference channel 4 and the width of the measurement channel 6 may be at least 10 microns. The width of the reference channel 4 and the width of the measurement channel 6 may, for example, be up to 500 microns. The depth of the reference channel 4 and the depth of the measurement channel 6 may, for example, be at least 10 microns. The depth of the reference channel 4 and the depth of the measurement channel 6 may, for example, be up to 250 microns. The diameter of the measurement chamber 21 may, for example, be at least 0.5 mm. The diameter of the measurement chamber 21 may, for example, be up to 5 mm. The depth of the measurement chamber 21 may, for example, be at least 50 microns. The depth of the measurement chamber 21 may, for example, be up to 250 microns. The volume through which pressurized gas flows may, for example, be at least 0.1 mm. The volume through which pressurized gas flows may, for example, be up to 100 mm³. Reducing the volume through which pressurized gas flows increases the sensitivity of the differential pressure sensor to changes of pressure at the measurement outlet 16. One method of providing such small volumes involves fabricating a small scale differential pressure sensor using microfabrication techniques such as, for example, photolithography and/or deep reactive ion etching. It is to be understood that the term microfabrication refers to assembly of elements using techniques such as lithography, and is not intended to imply that everything fabricated is on the micron scale.

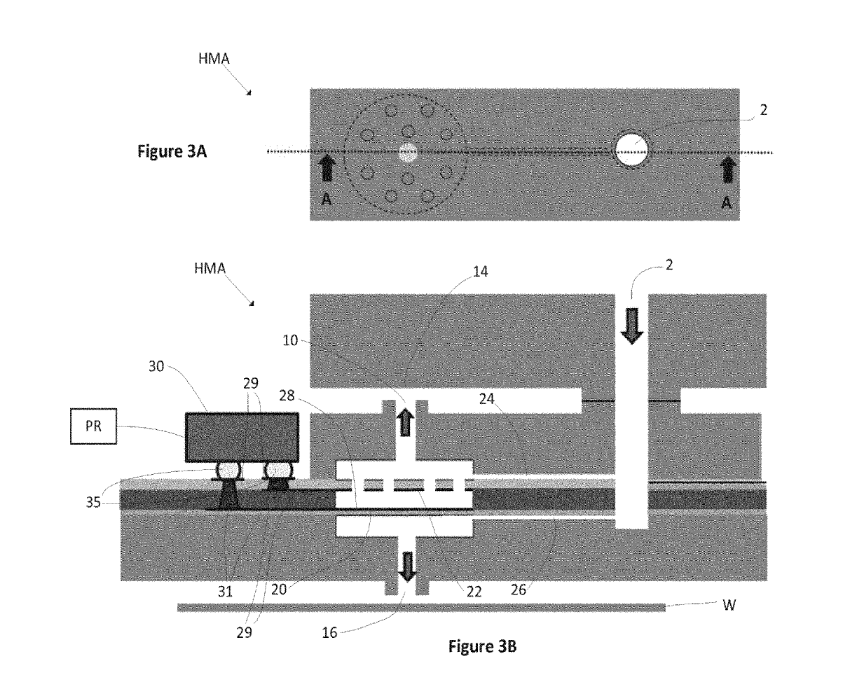

FIG. 3A is a schematic depiction of a height measurement apparatus when viewed from above according to an embodiment of the invention, the height measurement apparatus comprising a capacitor based differential pressure sensor. FIG. 3B is a schematic cross-sectional side view of the height measurement apparatus comprising a capacitor based differential pressure sensor. Pressurized gas is provided to the height measurement apparatus through an inlet 2. The pressurized gas leaves the height measurement apparatus from a reference outlet 10 and a measurement outlet 16. The reference outlet 10 is a predetermined distance from a reference surface 14. The measurement outlet 16 is an unknown distance from a substrate W. A reference channel 24 provides fluid communication between the reference outlet 10 and the inlet 2. A measurement channel 26 provides fluid communication between the measurement outlet 16 and the inlet 2. The reference channel 24 and the measurement channel 26 may have small volumes in order to act as flow restrictors in providing a controlled and/or steady flow of pressurized gas to the reference outlet 10 and the measurement outlet 16. For example, the height of the reference channel 24 and the height of the measurement channel 26 may be at least 5 microns. The height of the reference channel 24 and the height of the measurement channel 26 may, for example, be up to 50 microns. The width of the reference channel 24 and the width of the measurement channel 26 may, for example, be at least 5 microns. The width of the reference channel 24 and the width of the measurement channel 26 may, for example, be up to 50 microns. The length of the reference channel 24 and the length of the measurement channel 26 may, for example, be at least 10 microns. The length of the reference channel 24 and the length of the measurement channel 26 may, for example, be up to 500 microns.

A flexible membrane 20 is provided between the reference outlet 10 and the measurement outlet 16 such that one side of the flexible membrane is in fluid communication with the reference outlet and the other side of the flexible membrane is in fluid communication with the measurement outlet. The flexible membrane 20 is provided with a flexible electrode 28. The flexible membrane 20 may be provided with the flexible electrode via known metal deposition techniques such as, for example, metal evaporation or sputtering. The flexible electrode may, for example, be formed from Aluminium, Gold, Platinum, Chromium or Titanium. A static perforated electrode 22 is provided opposite the flexible membrane 20 such that the flexible electrode 28 and the static perforated electrode form a capacitor. The flexible membrane 20 is configured to move when a pressure change occurs at the measurement outlet 16. When the flexible membrane 20 moves the separation between the flexible electrode 28 and the static perforated electrode 22 changes. Changing the separation between the flexible electrode 28 and the static perforated electrode 22 changes the capacitance of the capacitor formed from the flexible electrode and the static perforated electrode. Monitoring electronics 30 may be provided to monitor the capacitance of the capacitor. The monitoring electronics 30 may be connected to the flexible electrode on the flexible membrane 20 and the static perforated electrode 22 using conductors 29, and vias 31. Metal studs 35 formed from, for example, Gold may be used to provide a reliable interconnection between the monitoring electronics 30 and the conductors 29. An advantage of using a capacitor based differential pressure sensor is the insignificant impact of thermal noise on pressure measurements. This is because the capacitor based differential pressure sensor does not draw a significant electrical current (compared, for example, with the piezo-resistive based differential pressure sensor described below) and therefore does not suffer from thermal noise arising from heat generated by a significant electrical current flowing through a resistor. A processor PR may be provided, the processor being configured to receive an output signal from the monitoring electronics 30 and use that signal to determine the distance between the measurement outlet 16 and the substrate W.

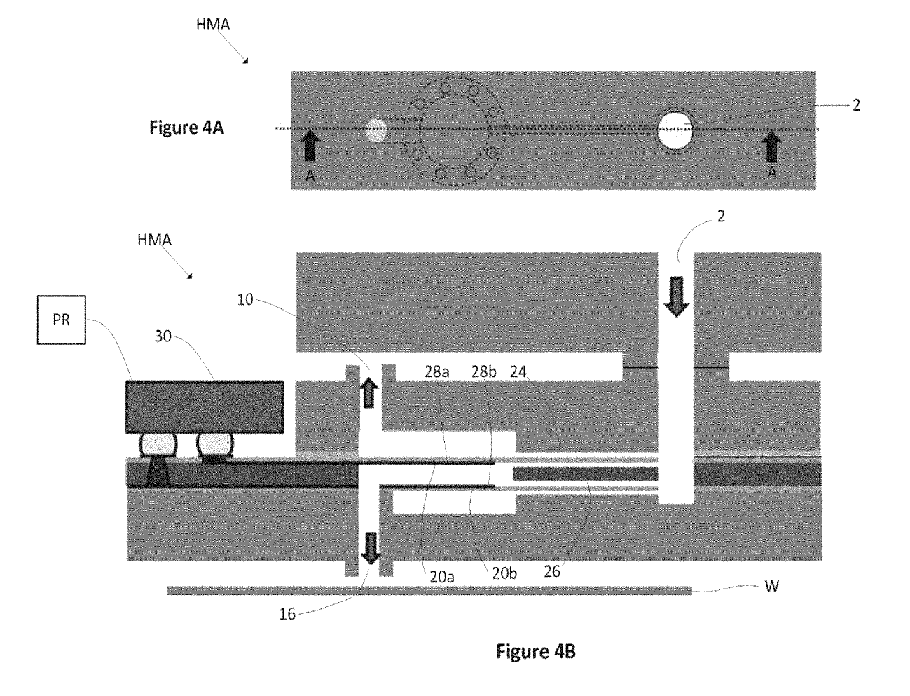

FIG. 4A is a schematic depiction of a view from above a height measurement apparatus according to an alternative embodiment of the invention, the height measurement apparatus comprising an alternative capacitor based differential pressure sensor. FIG. 4B is a schematic cross-sectional side view along line AA of the height measurement apparatus comprising the alternative capacitor based differential pressure sensor. In the embodiment of FIG. 4, two flexible membranes 20a, 20b are provided between the reference outlet 10 and the measurement outlet 16. A flexible electrode 28a, 28b is provided on each flexible membrane 20a, 20b such that the flexible electrodes form a capacitor. The flexible electrodes 28a, 28b may be considered to be examples of detection devices. Each flexible membrane 20a, 20b is configured to move when a pressure change occurs at the measurement outlet 16. When the flexible membranes 20 move the separation between the flexible electrodes 28 changes. Changing the separation between the two flexible electrodes 28a, 28b changes the capacitance of the capacitor formed from the two flexible electrodes. Monitoring electronics 30 may be provided to monitor the capacitance of the capacitor. An advantage of using two flexible electrodes 28a, 28b to form a capacitor based differential pressure sensor rather than one static perforated electrode 22 and one flexible electrode is that the resulting differential pressure sensor is more sensitive to pressure changes at the measurement outlet 16. The differential pressure sensor is more sensitive to pressure changes at the measurement outlet 16 because there is a greater total range of movement possible between two flexible electrodes compared to between one flexible electrode and one static electrode. However, this embodiment may be more difficult to manufacture than an embodiment comprising one flexible electrode 28 and a static perforated electrode 22.

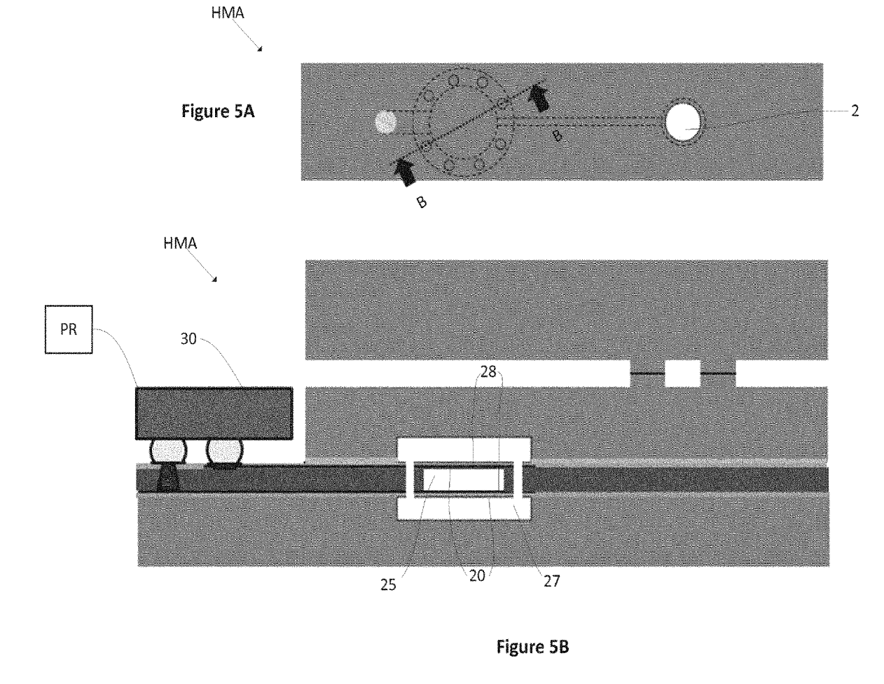

FIG. 5A is a schematic depiction of a rotated view from above the height measurement apparatus depicted in FIG. 4. FIG. 5B is a schematic cross-sectional side view along line BB of the height measurement apparatus depicted in FIG. 4. As may be seen from FIG. 4B and FIG. 5B, a volume 25 between the flexible electrodes 28 is in fluid communication with the measurement channel 26. A volume 27 surrounding the flexible electrodes 28 is in fluid communication with the reference channel 24.

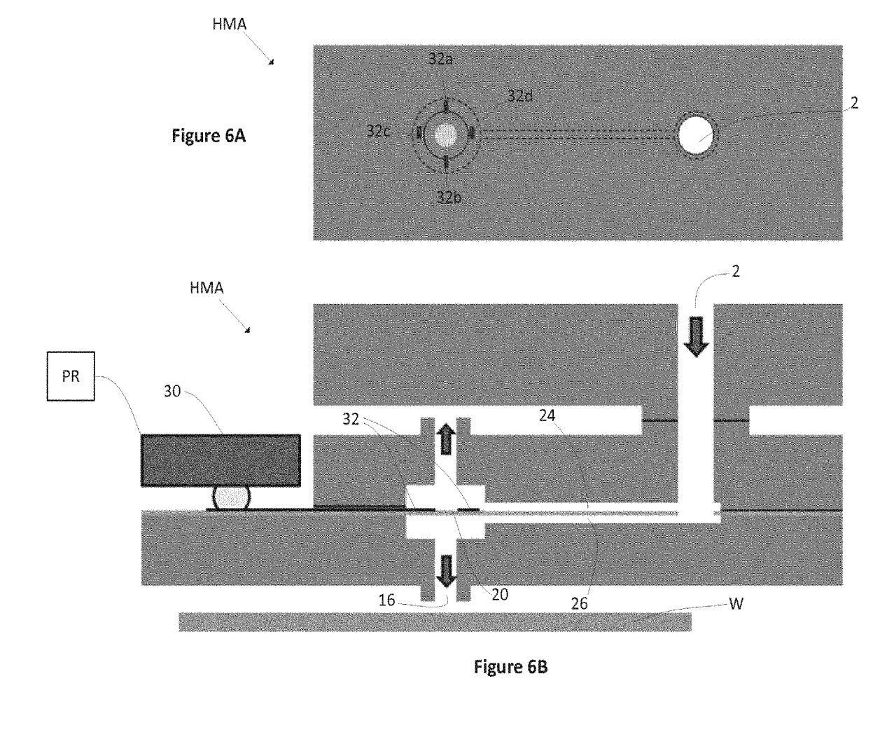

The differential pressure sensor used in a height measurement apparatus need not be capacitor based. Alternative embodiments of the invention are possible. For example, FIG. 6A is a schematic view from above a height measurement apparatus according to an embodiment of the invention, the height measurement apparatus comprising a piezo-resistive based differential pressure sensor. FIG. 6B is a schematic cross-sectional side view of the height measurement apparatus comprising a piezo-resistive based differential pressure sensor. A piezo-resistive element 32 may be provided on the flexible membrane 20. The piezo-resistive element may be considered to be an example of a detection device. The piezo-resistive element 32 may be configured to undergo mechanical strain when the flexible membrane 20 moves. The mechanical strain experienced by the piezo-resistive element 32 may change the electrical resistance of the piezo-resistive element. Monitoring electronics 30 may be provided to monitor the electrical resistance of the piezo-resistive element 32. A processor PR may be provided, the processor being configured to receive an output signal from the monitoring electronics 30 and use that signal to determine the distance between the measurement outlet 16 and the substrate W.

In the embodiment of FIG. 6A, the flexible membrane 20 is provided with four piezo-resistive elements 32a, 32b, 32c and 32d. The piezo resistive elements depicted in FIG. 6A are substantially rectangular. However, the piezo-resistive elements may take any desired shape. The flexible membrane 20 is substantially circular. Two of the piezo-resistive elements 32a, 32b are oriented on the flexible membrane 20 such that they are substantially parallel with the radius of the flexible membrane. The other two piezo-resistive elements 32c, 32d are oriented such that they are substantially perpendicular to the radius of the flexible membrane 20. When the flexible membrane 20 moves as a result of a pressure change at the measurement outlet 16, its radius increases. Two of the piezo-resistive elements 32a, 32b experience a significant mechanical strain when the flexible membrane 20 moves due to their orientation compared to the other two piezo-resistive elements 32c, 32d. Two of the piezo-resistive elements 32a, 32b therefore experience a significant change in resistance when the flexible membrane 20 moves. The other two piezo-resistive elements 32c, 32d experience an insignificant change in resistance when the flexible membrane 20 moves.

All four piezo-resistive elements 32a, 32b, 32c, 32d experience substantially the same background environmental effects such as, for example, resistance changes due to temperature changes. The background environmental effects may contribute noise to substrate height measurements. The resistances of two of the piezo-resistive elements 32c, 32d are independent of the movement of the flexible membrane 20, but are dependent on background environmental effects. Those two piezo-resistive elements 32c, 32d may therefore be used to provide measurements that are indicative of the noise generated by background environmental effects. Measurements indicative of background environmental effects may be used to reducing noise generated by background environmental effects from substrate height measurements.

The two piezo-resistive elements 32a, 32b that are configured to experience a significant change in resistance when the flexible membrane 20 moves may be referred to as measurement elements. Measurement elements are used to provide substrate height measurements. That is, pressure changes at the measurement outlet 16 result in changes of the resistance of measurement elements. The two piezo resistive elements 32c, 32d that are configured to experience an insignificant change in resistance when the flexible membrane moves may be referred to as reference elements. Reference elements are used to provide reference measurements. That is, pressure changes at the measurement outlet 16 do not significantly change the resistance of the reference elements. It may preferable to have a substantially circular flexible membrane 20 when providing the flexible membrane with reference elements and measurement elements. If the flexible membrane was not circular, when the flexible membrane moved the distortion of the flexible membrane may not be radially uniform. Non-uniform distortion of the flexible membrane may result in reference elements experiencing a significant mechanical strain when the flexible membrane moves. The reference elements may experience a significant change in resistance when the flexible membrane moves, hence they may not be suitable for reducing noise generated by background environmental effects from substrate height measurements. However, in some cases it may be preferable to have a non-circular flexible membrane, e.g. a square or rectangular flexible membrane. That is, it may be preferable to have a polygonal flexible membrane. The flexible membrane may, for example, have at least three vertices. Certain regions on a non-circular flexible membrane may impart a large mechanical strain on a piezo-resistive element situated at those regions. For example, a piezo-resistive element may be situated at a region on a non-circular flexible membrane that experiences a large change in mechanical strain when the flexible membrane moves. The large change in mechanical strain may result in a large change of resistance of the piezo-resistive element. The large change in resistance may increase the sensitivity of the piezo-resistive based differential pressure sensor to pressure changes at the measurement outlet 16.

In general, at least one piezo-resistive element may be configured to experience a significant change in resistance when the flexible membrane 20 moves and at least one other piezo-resistive element may be configured to experience an insignificant change in resistance when the flexible membrane 20 moves. The orientation, shape and/or location of the piezo-resistive elements may be selected to provide a desired change in resistance when the flexible membrane 20 moves. For example, a region at the edge of the flexible membrane 20 may experience a greater deformation than a region at the centre of the flexible membrane when the flexible membrane moves. A piezo-resistive element located at the edge of the flexible membrane 20 may therefore experience a greater change in resistance when the flexible membrane moves compared to a piezo-resistive element located at the centre of the flexible membrane. The resistance of a piezo-resistive element located at the edge of the flexible membrane may therefore have a greater sensitivity to the movement of the flexible membrane. A piezo-resistive element located at the edge of the flexible membrane may be referred to as a measurement element.

The four piezo-resistive elements 32a, 32b, 32c, 32d may be arranged in a Wheatstone bridge circuit configuration. That is, the four piezo-resistive elements may take the place of four resistors in a conventional Wheatstone bridge circuit. An advantage of using a Wheatstone bridge circuit configuration of piezo-resistive elements is that the effects of temperature on an output signal of the bridge circuit are compensated for. That is, the detected change in resistance of a piezo-resistive element in the bridge circuit is due to pressure changes at the measurement outlet 16 rather than a changing temperature of the piezo-resistive element.

In general, any circuit arrangement that allows for the detection of a change of resistance of the piezo-resistive elements 32 may be used. For example, the piezo-resistive elements 32 may be arranged to form part of a four-wire resistance measurement circuit. This involves forcing a constant current through a piezo-resistive element and measuring the voltage change across the piezo-resistive element when its resistance changes. Another example circuit arrangement that enables resistance measurements involves arranging the piezo-resistive elements 32 to form part of a voltage divider circuit. For example, two piezo-resistive elements 32 may be connected in series and a constant voltage (or a constant current) may be applied across them. The voltage change across one of the piezo resistive elements 32 may be monitored and used to determine the resistance of the piezo-resistive element. One of the piezo-resistive elements 32 in the voltage divider circuit may be configured to be a reference element whereas the other piezo-resistive element in the voltage divider circuit may be configured to be a measurement element. Alternatively, both piezo-resistive elements 32 in the voltage divider circuit may be configured to be measurement elements, with one piezo-resistive element providing a positive contribution to the output signal and the other piezo-resistive element providing a negative contribution to the output signal for the same flexible membrane movement.

Monitoring electronics 30 may be provided to monitor the electrical resistance of a piezo-resistive element 32. The monitoring electronics 30 may be connected to the piezo-resistive element 32 by a conductor such as, for example, a thin metallic layer. The monitoring electronics 30 may, for example, comprise an amplifier and an analogue to digital converter configured to provide an output signal indicative of the resistance of the piezo-resistive element 32. A processor PR may be provided, the processor being configured to receive an output signal from the monitoring electronics 30 and use that signal to determine the distance between the measurement outlet 16 and the substrate W.

Background electronic noise may be present in the output signal of the monitoring electronics 30. For example, the piezo-resistive elements 32 may exhibit Johnson noise caused by thermal agitation of charge carriers in the piezo-resistive elements. Any background electronic noise present in the output signal originating from the measurement elements may be reduced by, for example, deducting the output signal originating from the reference elements from the output signal originating from the measurement elements.

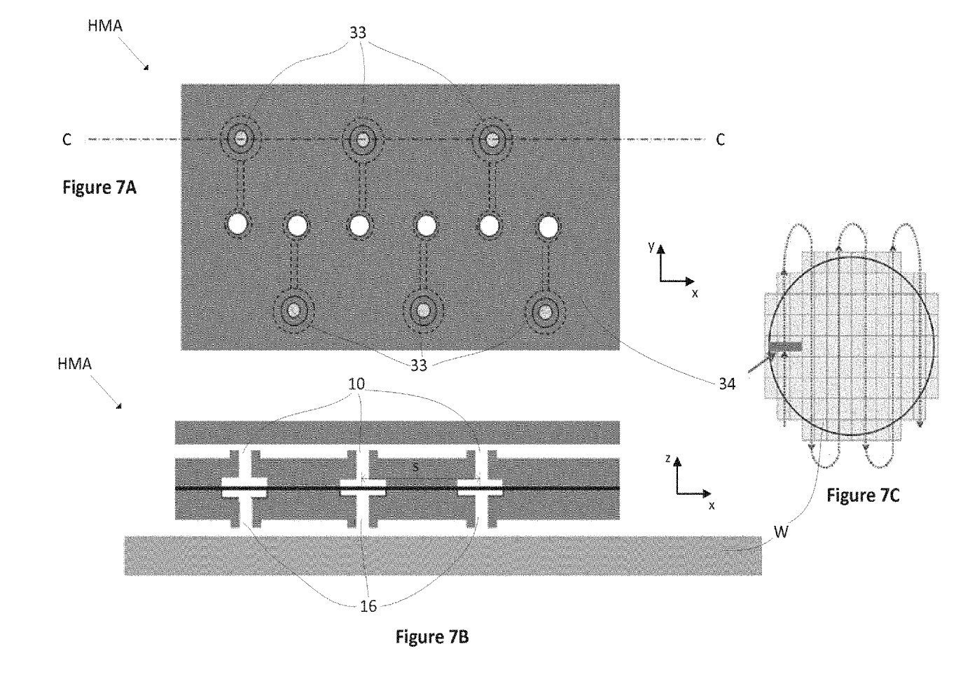

FIG. 7A is a schematic depiction of a view from above of a height measurement apparatus according to an embodiment of the invention, the height measurement apparatus comprising an array of piezo-resistive based differential pressure sensors. FIG. 7B is a schematic cross-sectional side view of the height measurement apparatus along line CC. FIG. 7C schematically depicts using the height measurement apparatus comprising an array of differential pressure sensors to traverse an example path across a surface of a substrate. Using an array of differential pressure sensors 34 to measure the height of a substrate W takes less time than using a single differential pressure sensor. This is because an array of differential pressure sensors may measure the substrate W height across a greater surface area than a single differential pressure sensor. The path across the substrate W depicted by the dashed line and arrows in FIG. 7C is one example of a route through which the height measurement apparatus HMA may be scanned across a substrate W. In general, the height measurement apparatus HMA may be scanned through any desired path across the whole or part of a substrate W. The direction in which the height measurement apparatus HMA is scanned across a substrate W may be referred to as a scanning direction. A direction substantially perpendicular to the scanning direction may be referred to as a non-scanning direction.

In the embodiment of FIG. 7 the array 34 consists of six differential pressure sensors 33 configured in two rows consisting of three differential pressure sensors per row. The two rows are slightly offset from each other along the x axis to provide a compact array 34 of differential pressure sensors 33. In general, an array of differential pressure sensors comprises a plurality of differential pressure sensors. The number of differential pressure sensors in an array may, for example, be at least 3. The number of differential pressure sensors in an array may, for example, be up to 256. For example, differential pressure sensors may be used to form a differential pressure sensor array 34. Adjacent differential pressure sensors in the array may have a periodic spacing s (e.g. measured as the distance between the centres of adjacent flexible membranes). The spacing between adjacent differential pressure sensors in the array may, for example, be 3 mm or less. The spacing between adjacent differential pressure sensors in the array may, for example, be 2 mm or less. The spacing between adjacent differential pressure sensors in the array may, for example, be 1 mm or more. The spacing between adjacent differential pressure sensors in the array may, for example, be around 1.5 mm. The total length in the non-scanning direction of an array comprising 36 differential pressure sensors may, for example, be approximately 5.5 cm. The values of spacing provided here are not limited to a height measurement apparatus comprising an array of 36 differential pressure sensors. The numbers of differential pressure sensors given as examples here do not include a reference sensor, which is described below. The configuration of differential pressure sensors in the array may vary. For example, the array 34 may comprise a checkerboard pattern of differential pressure sensors. In general, any number of differential pressure sensors may be arranged in any desired configuration to form an array 34.

In general, a height measurement apparatus HMA comprising an array of any form of differential pressure sensors may be used to measure the height of a substrate W in the manner depicted in FIG. 7C. For example, a height measurement apparatus HMA comprising an array of capacitor based differential pressure sensors, e.g. those depicted in FIG. 3 and FIG. 4, may be used to measure the height of a substrate W in the manner depicted in FIG. 7C.

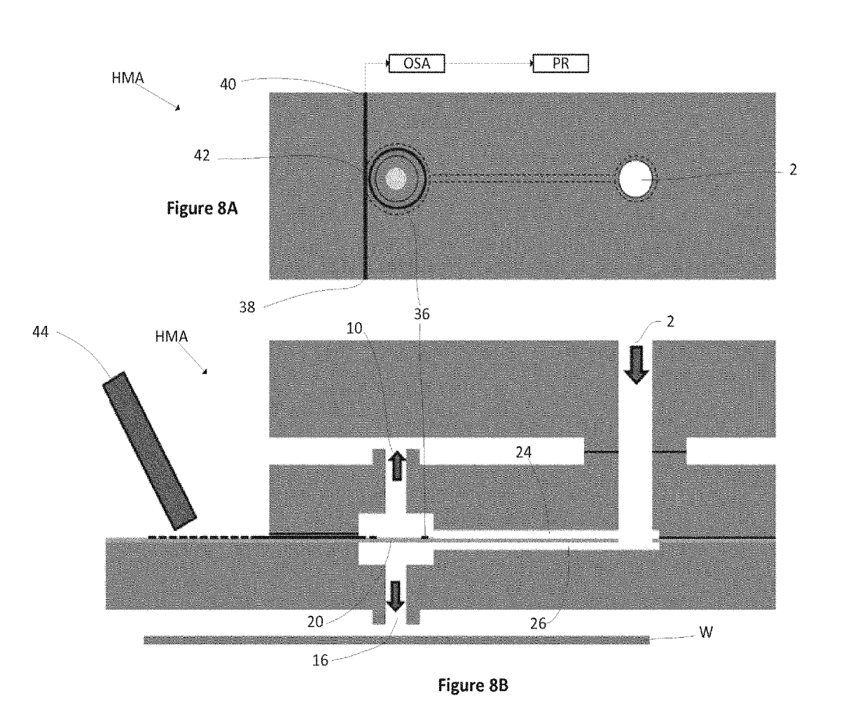

FIG. 8A is a schematic view from above a height measurement apparatus according to an alternative embodiment of the invention, the height measurement apparatus comprising an optical ring resonator based differential pressure sensor. FIG. 8B is a schematic cross-sectional side view of the height measurement apparatus comprising an optical ring resonator based differential pressure sensor. The flexible membrane 20 is provided with a flexible optical resonator 36 such that the height measurement apparatus HMA comprises a flexible optical resonator based differential pressure sensor. The flexible optical resonator 36 may be considered to be an example of a detection device. A resonant frequency of the flexible optical resonator 36 may be defined by the optical path length of the flexible optical resonator. The flexible optical resonator 36 may be configured such that the optical path length, and thus the resonant frequency, of the flexible optical resonator 36 changes when the flexible membrane 20 moves. An optical input 38 and an optical output 40 may be coupled to the flexible optical resonator 36. Radiation may be provided to the flexible optical resonator 36 by the optical input 38. The radiation provided by the optical input 38 may resonate within the flexible optical resonator 36 if the wavelength of the radiation is a resonant wavelength of the flexible optical resonator. The flexible optical resonator 36 may act as a filter for radiation having the resonant wavelength of the flexible optical resonator. The optical spectrum of radiation exiting the optical output 40 may be dependent on the resonant frequency of the flexible optical resonator 36 which, in turn, is dependent on the movement of the flexible membrane 20. An optical spectrum analyser OSA may be provided to analyse a spectrum of radiation exiting the optical output 40. A processor PR may be provided, the processor being configured to receive an output signal from the optical spectrum analyser OSA and use that signal to determine the distance between the measurement outlet 16 and the substrate W.

In the embodiment of FIG. 8, the flexible optical resonator 36 is a flexible optical ring resonator. The optical ring resonator 36 is provided on a circular flexible membrane 20. The circular flexible membrane 20 is provided with a waveguide 42. In the embodiment of FIG. 8, the waveguide 42 provides the optical input 38 and the optical output 40 for the optical ring resonator 36. The waveguide 42 is optically coupled to the optical ring resonator 36. Optical coupling between the waveguide 42 and the optical ring resonator 36 may be achieved by locating the waveguide sufficiently close to the optical ring resonator. For example, the waveguide 42 may be provided approximately 200 nm from the optical ring resonator 36.

In the embodiment of FIG. 8 an optical fibre 44 provides radiation to the waveguide 42. The radiation provided by the optical fibre 44 may be broadband radiation. The radiation provided by the optical fibre 44 may, for example, have a minimum wavelength of approximately 500 nm. The radiation provided by the optical fibre 44 may, for example, have a maximum wavelength of approximately 2000 nm. The range of wavelengths may be wider in some embodiments. Because the waveguide 42 and the optical ring resonator 36 are coupled, the frequency content of the output signal of the optical output 40 depends on the resonant frequency of the optical ring resonator. The resonant frequency of the optical ring resonator 36 depends on the diameter of the optical ring resonator. The diameter of the optical ring resonator 36 changes when the flexible membrane 20 moves. Movement of the flexible membrane 20 depends on the pressure at the measurement outlet 16. An optical spectrum analyser OSA may be provided to analyse the frequency content of an output signal of the optical output 40. A processor PR may be provided, the processor being configured to receive an output signal from the optical spectrum analyser OSA and use that signal to determine the distance between the measurement outlet 16 and the substrate W.

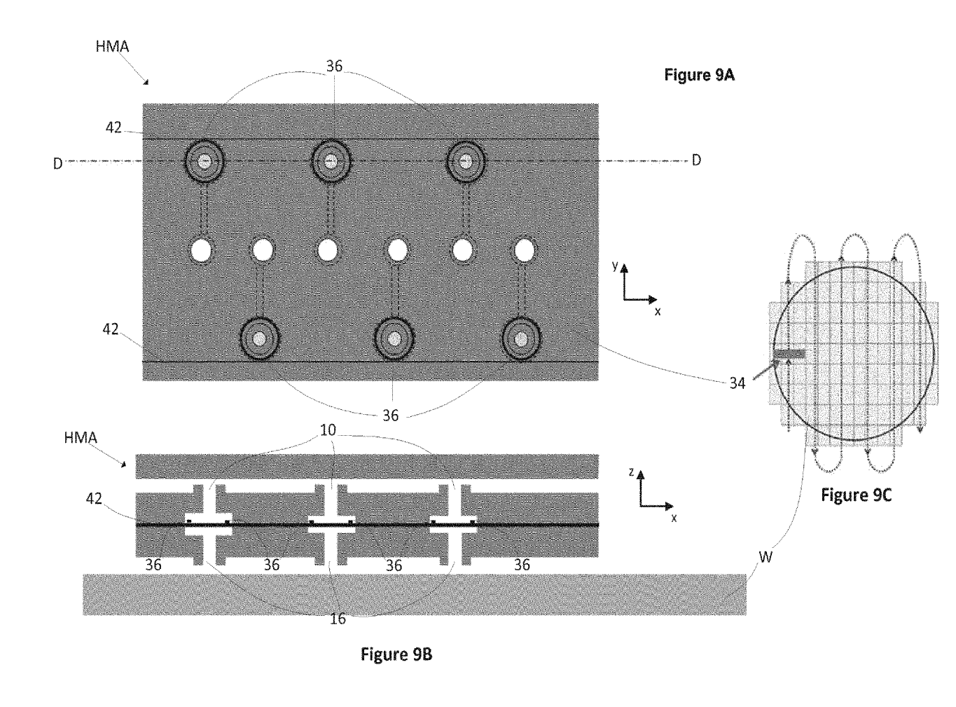

FIG. 9A is a schematic view from above a height measurement apparatus according to an alternative embodiment of the invention, the height measurement apparatus comprising an array of optical ring resonator based differential pressure sensors. The optical ring resonators may be considered to be examples of detection devices. FIG. 9B is a schematic cross-sectional side view of the height measurement apparatus along line DD. FIG. 9C schematically depicts using the height measurement apparatus comprising an array of differential pressure sensors to traverse an example path across a surface of a substrate. One waveguide 42 may be coupled to multiple optical ring resonators 36 in the array 34 of differential pressure sensors. At least one optical ring resonator 36 in the array 34 of differential pressure sensors may have a unique diameter. All of the optical ring resonators 36 in the array 34 may have different diameters. The diameters of the optical ring resonators 36 may be selected such that each optical ring resonator in the array has a unique range of possible resonant frequencies. Providing each optical ring resonator 36 in the array 34 with a different diameter allows for the output signal of every differential pressure sensor in the array to be analysed using a single optical spectrum analyser OSA.

Another alternative embodiment of the present invention involves providing the flexible membrane with a Mach-Zehnder interferometer. The Mach-Zehnder interferometer may be considered to be an example of a detection device. The Mach-Zehnder interferometer may comprise a waveguide that splits into a reference arm and a measurement arm before recombining into a waveguide via a coupler. The measurement arm may be configured to move when the flexible membrane moves. That is, the optical path length of the measurement arm may depend on movement of the flexible membrane. The reference arm may be not be located on the flexible membrane such that the optical path length of the reference arm is independent of the movement of the flexible membrane. The waveguide may be provided with coherent radiation, e.g. light from a laser. The coherent radiation is split between the reference arm and the measurement arm. The coherent radiation travels down the reference arm and the measurement arm and then recombines at the coupler. The coherent radiation that travelled through the reference arm may interfere with the coherent radiation that travelled through the measurement arm upon recombination. Interference between the coherent radiation may depend on the optical path length difference between the measurement arm and the reference arm. The recombined radiation may then travel through the waveguide and be incident upon a photodetector. An intensity detected by the photodetector may depend on the optical path length difference between the reference arm and the measurement arm, which in turn may depend on the movement of the flexible membrane. A processor PR may be provided, the processor being configured to receive an output signal from the photodetector and use that signal to determine the distance between the measurement outlet 16 and the substrate W.

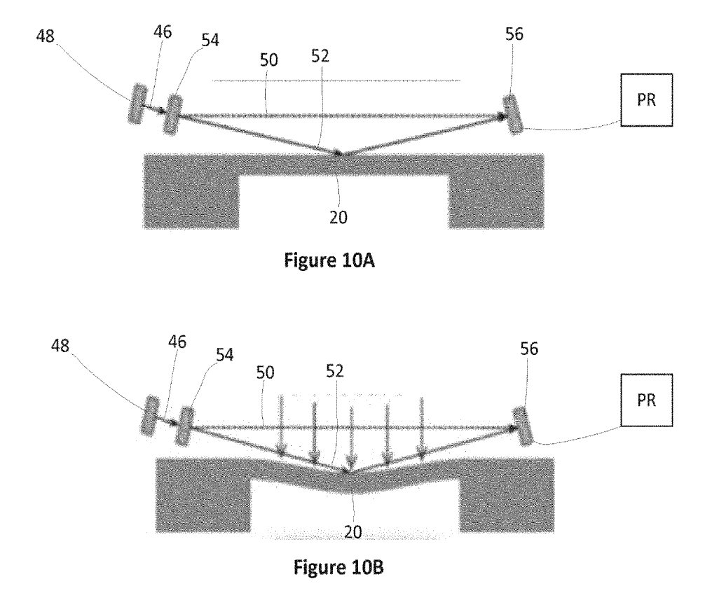

A yet further alternative embodiment of the present invention involves providing the flexible membrane 20 with a reflective portion configured to reflect incident radiation. The reflective portion may be considered to be an example of a detection device. FIG. 10A is a schematic depiction of an interferometric based differential pressure sensor according to an embodiment of the invention. In the embodiment of FIG. 10A no pressure is applied to the flexible membrane 20. FIG. 10B is a schematic depiction of an interferometric based differential pressure sensor with pressure applied to the flexible membrane. Radiation 46 is provided by a laser 48. The radiation 46 is split into two beams 50, 52 by a beam splitter 54. A first beam 50 is directed towards a photodetector 56. A second beam 52 is incident on the reflective portion of the flexible membrane 20 wherefrom the second beam reflects and is incident on the photodetector 56. The two beams 50, 52 interfere with each other at the photodetector 56. The interference between the two beams 50, 52 is dependent on their phase difference. The phase difference of the two beams 50, 52 is in turn dependent on their optical path length difference. An optical path length of the first beam 50 may be a predetermined value. An optical path length of the second beam 52, and thus the interference between the two beams, is dependent on the movement of the flexible membrane 20. An intensity detected by the photodetector 56 is therefore dependent on the movement of the flexible membrane 20. The embodiment depicted by FIG. 10 may form part of a height measurement apparatus that has a corresponding configuration to embodiments of the height measurement apparatus depicted in, for example, FIG. 3 or FIG. 7. A processor PR may be provided, the processor being configured to receive an output signal from the photodetector 56 and use that signal to determine the distance between a measurement outlet and a substrate.

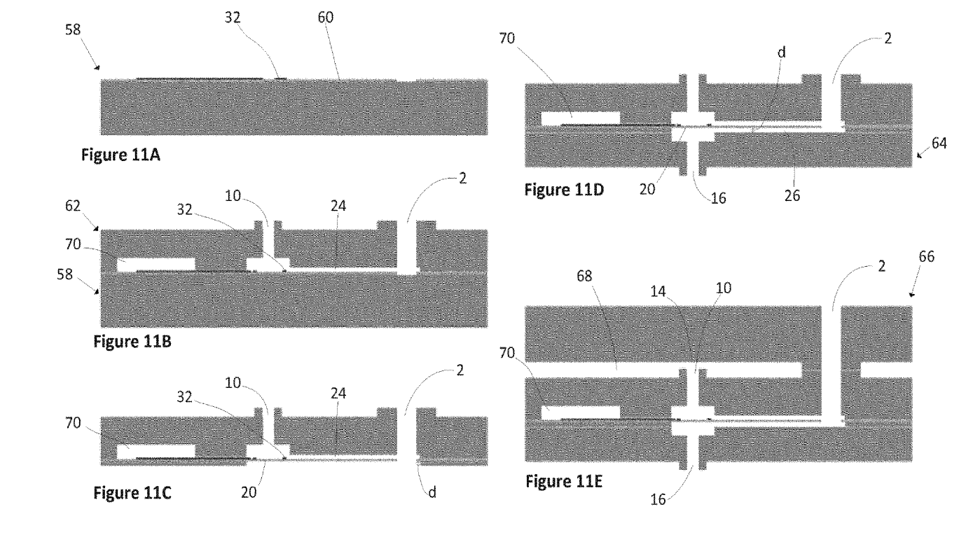

FIG. 11 is a schematic depiction of five stages A, B, C, D and E involved in manufacturing a height measurement apparatus according to an embodiment of the invention. In the example of FIG. 11, the height measurement apparatus being manufactured comprises a piezo-resistive based differential pressure sensor, such as that depicted in FIG. 6. In general, the manufacturing stages depicted in FIG. 11 and the associated microfabrication techniques described herein may be used to manufacture height measurement apparatus comprising any type of differential pressure sensor. For example, the manufacturing stages may be used to manufacture a height measurement apparatus comprising a flexible optical resonator based differential pressure sensor and/or an interferometric based differential pressure sensor.

The manufacturing process begins with a silicon on insulator wafer 58, as schematically depicted in FIG. 11A. The silicon on insulator wafer comprises three layers. The first layer comprises bulk silicon, and may be referred to as the handle. The second layer is located on top of the handle and is significantly thinner than the handle. The second layer comprises silicon dioxide, and may be referred to as the buried oxide layer (or box layer). The third layer is located on top of the box layer. The third layer comprises a thin layer of silicon, and may be referred to as the device layer. The silicon on insulator wafer 58 may have a predetermined device layer 60 thickness. The thickness of the device layer 60 of the silicon on insulator wafer 58 may, for example, be approximately 5 microns. A piezo-resistive element 32 is provided on the device layer 60 using conventional microfabrication techniques such as, for example, thermal oxidation, ion implantation, photolithography, diffusion, annealing, dielectric deposition, metal deposition and/or etching.

The next step in the manufacturing process involves providing a second silicon on insulator wafer 62 with an inlet 2, a reference channel 24 and a reference outlet 10. The inlet 2, reference channel 24 and the reference outlet 10 are in fluid communication with each other. The second silicon on insulator wafer 62 may be formed using known microfabrication techniques such as photolithography and deep reactive ion etching. The second silicon on insulator wafer may further comprise a device chamber 70. The device chamber 70 may accommodate monitoring electronics and/or optics configured to provide an output signal indicative of the pressure at the measurement outlet 16. The device chamber 70 may be formed using known microfabrication techniques such as photolithography and deep reactive ion etching.

The next manufacturing step is to bond the second silicon on insulator wafer 62 with the first silicon on insulator wafer 58 such that a continuous path exists from the inlet 2, through the reference channel 24, past the piezo-resistive element 32 and through the reference outlet 10, as schematically depicted in FIG. 11B. The bonding may be achieved by conventional wafer bonding techniques such as, for example, adhesive bonding or fusion bonding.

The next step in the manufacturing process involves thinning the first silicon on insulator wafer from underneath, i.e. thinning the handle of the first silicon on insulator wafer 58. This may be achieved by, for example, wafer backgrinding. The handle of the first silicon on insulator wafer 58 may be ground away until the thickness of the handle corresponds with a desired thickness d of the measurement channel. The measurement channel 26, as depicted in FIG. 11D, may then be formed by, for example, a photolithographic process and deep reactive ion etching until a box layer of the first wafer is reached, as schematically depicted in FIG. 11C. Backgrinding may be too inaccurate to form a measurement channel 26 with a predetermined thickness d. The box layer may, for example have a thickness of at least 0.5 mm. The box layer may, for example have a thickness of up to 1 mm. The box layer may be removed after the deep reactive ion etching process to reveal the device layer. The box layer may be removed using a reactive ion etching process. The device layer of the first wafer may act as the flexible membrane 20. The thickness of the device layer may be altered to achieve a flexible membrane 20 of a desired thickness. The measurement channel 26 is in fluid communication with the inlet 2.

The next step in the manufacturing process involves providing a third silicon on insulator wafer 64 with a measurement outlet 16. The third silicon on insulator wafer 64 may be formed using conventional microfabrication techniques such as photolithography and deep reactive ion etching.

The next manufacturing step is to bond the third silicon on insulator wafer 64 with the first silicon on insulator wafer 58 and second silicon on insulator wafer 62 such that a continuous path exists from the inlet 2, through the measurement channel 26, past the flexible membrane 20 and through the measurement outlet 16, as schematically depicted in FIG. 11D. The measurement channel 26 is defined once the third silicon on insulator wafer and the first silicon on insulator wafer are bonded together.

The next step in the manufacturing process involves providing a fourth silicon on insulator wafer 66 with an inlet 2 and a reference outlet channel 68. The fourth silicon on insulator wafer 66 may be formed using known microfabrication techniques such as photolithography and deep reactive ion etching.

The next manufacturing step is to bond the fourth silicon on insulator wafer 66 with the second silicon on insulator wafer 62 such that the inlet 2 of the fourth silicon on insulator wafer is in alignment with the inlet of the second silicon on insulator wafer and the reference outlet channel 68 is in fluid communication with the reference outlet 10, as schematically depicted in FIG. 11E.

Although the manufacturing process detailed above and depicted in FIG. 11 has been described solely with silicon on insulator wafers, it will be appreciated by a person skilled in the art that any other suitable type of wafer may instead be used. For example, metallic or ceramic materials may be used to form a height measurement apparatus. However, using silicon is preferable as precise and reproducible fabrication of height measurement apparatus may be more difficult to achieve with other materials. The use of silicon on insulator wafers with known microfabrication techniques allows for the precise and reproducible fabrication of height measurement apparatus. An array of height measurement apparatus may be fabricated using four silicon on insulator wafers such that the differential pressure sensors in the array are fabricated on the same wafers. Differential pressure sensors fabricated on the same wafers have substantially the same characteristics such as, for example, measurement channel lengths, flexible membrane thicknesses and the predetermined distance between the reference surface 14 and the reference outlet 10. The differential pressure sensors fabricated on the same wafers may be cut out in an array, such as those shown in FIG. 7A and FIG. 9A. Alternatively, once a number of height measurement apparatus have been fabricated on a substrate stack, the substrate stack may be cut to form individual height measurement apparatus. Individual height measurement apparatus may be assembled into a larger height measurement apparatus comprising an array of differential pressure sensors. However, assembling individual height measurement apparatus into an array may require great precision and is therefore not preferred.

In use, pressurized gas is provided to the inlet 2 of the fourth silicon on insulator wafer 66. The pressurized gas may be provided by a source held at a constant pressure. The constant pressure at which the source is held may depend on the extent to which the mass flow of pressurized gas is restricted within the differential pressure sensor, e.g. the dimensions of the reference channel 24 and measurement channel 26. The pressurized gas may be held at a pressure of at least 0.1 bar. The pressurized gas may be held at a pressure of up to 5 bar. The pressurized gas may, for example, be held at a pressure of 1 bar. The pressurized gas may be, for example, air. The reference outlet channel 68 of the fourth silicon on insulator wafer 66 provides a reference surface 14 opposite the reference outlet 10. The reference surface 14 may be a predetermined distance from the reference outlet 10.

The height measurement apparatus may further comprise a reference sensor. The reference sensor may correspond to the differential pressure sensors in the array. However, the reference sensor may not be connected to a source of pressurized gas. As a result, the reference sensor may provide an output signal that is indicative of background noise present in substrate height measurements. The output signal of the reference sensor may be deducted from the output signals of other differential pressure sensors in the array in order to remove background noise from the substrate height measurements made by the array. For example, thermal noise present in the output signal of the array of differential pressure sensors may also be present in the output signal of the reference sensor. The output signal of the reference sensor may be deducted from the output signal of the array of differential pressure sensors in order to reduce the effect of thermal noise on the measured substrate height.

The embodiments described herein provide the advantage of reducing the time taken to accurately measure the height of a substrate compared with conventional systems such as, for example, measuring the height of a substrate with a single air gauge. Reducing the time taken to accurately measure the height of a substrate has a positive effect on the throughput of a lithographic apparatus because accurate lithographic exposures cannot take place until the height of the substrate is known. The embodiments described herein may be beneficially compared with conventional systems such as, for example, using a single air gauge rather than an array of differential pressure sensors to measure the height of a substrate. A further advantage provided by the embodiments described herein is that the bandwidth of the differential pressure sensors is relatively high when compared with the bandwidth of conventional air gauge systems. This is because the differential pressure sensors measure pressure changes via monitoring a deflection of a flexible membrane, whereas conventional air gauge systems measure pressure changes via monitoring changes in mass flow rate.

A conventional system for measuring the height of a substrate involves scanning a substrate underneath a measurement outlet of a single air gauge in order to determine the height of the substrate. Pressurized gas such as, for example, air is provided to the air gauge and is split into two channels, a reference channel and a measurement channel. Air exits the reference channel via a reference outlet which is a known distance from a reference surface. Air exits the measurement channel via a measurement outlet which is an unknown distance from the surface of the substrate. A mass flow sensor is provided between the reference channel and the measurement channel such that the mass flow sensor is in fluid communication with both the reference outlet and the measurement outlet. The mass flow sensor monitors changes in the mass flow rate of air between the reference channel and the measurement channel. As the distance between the measurement outlet and the substrate changes, the mass flow rate through the mass flow sensor changes. The height of the substrate may be determined from an output of the mass flow sensor.

Various embodiments of a detection device provided on the flexible membrane have been described. Other forms of detection device may be provided on the flexible membrane.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

The illumination optics, optics and detection optics may encompass various types of optical components, including refractive, reflective, and catadioptric optical components for directing, shaping, or controlling the beam of radiation.

The term “EUV radiation” may be considered to encompass electromagnetic radiation having a wavelength within the range of 4-20 nm, for example within the range of 13-14 nm. EUV radiation may have a wavelength of less than 10 nm, for example within the range of 4-10 nm such as 6.7 nm or 6.8 nm.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-30. (canceled)

31. A height measurement apparatus comprising an array of differential pressure sensors wherein adjacent differential pressure sensors have a periodic spacing, each differential pressure sensor comprising:
a reference outlet and a measurement outlet, the reference outlet being at a predetermined distance from a reference surface;
an inlet configured to provide pressurized gas for the reference outlet and the measurement outlet;
a flexible membrane positioned such that a reference side of the flexible membrane is in fluid communication with the reference outlet and a measurement side of the flexible membrane is in fluid communication with the measurement outlet, the flexible membrane being configured to move when a pressure change occurs at the measurement outlet; and
a detector configured to monitor movement of the flexible membrane.

32. The height measurement apparatus of claim 31, wherein a reference channel and a measurement channel are provided, the reference channel being configured to provide fluid communication between the inlet and the reference side of the flexible membrane, and the measurement channel being configured to provide fluid communication between the inlet and the measurement side of the flexible membrane.

33. The height measurement apparatus of claim 32, wherein the reference channel and the measurement channel are configured to act as flow restrictors.

34. The height measurement apparatus of claims 31, wherein the detector comprises a detection device provided on the flexible membrane.

35. The height measurement apparatus of claim 34, wherein the detection device comprises at least one piezo-resistive element.

36. The height measurement apparatus of claim 34, wherein the detection device comprises a flexible electrode.

37. The height measurement apparatus of claim 36, wherein the detector further comprises a static perforated electrode provided opposite the flexible electrode such that the flexible electrode and the static perforated electrode form a capacitor.

38. The height measurement apparatus of claim 34, wherein the detection device comprises a flexible optical resonator.

39. The height measurement apparatus of claim 38, wherein a waveguide is provided on the flexible membrane, the waveguide being configured to provide broadband radiation to the flexible optical resonator.

40. The height measurement apparatus of claim 34, wherein the detection device comprises a reflective portion configured to reflect incident radiation towards a photodetector.

41. The height measurement apparatus of claim 31, wherein the array is fabricated from a substrate stack.

42. The height measurement apparatus of claim 31, wherein the substrate stack comprises a plurality of semiconductor wafers.

43. The height measurement apparatus of claims 31, wherein the height measurement apparatus further comprises a reference sensor, the reference sensor comprising:
a reference outlet and a measurement outlet, the reference outlet being a predetermined distance from a reference surface;
a flexible membrane positioned such that a reference side of the flexible membrane is in fluid communication with the reference outlet and a measurement side of the flexible membrane is in fluid communication with the measurement outlet;
and a detector configured to monitor the movement of the flexible membrane;
wherein the reference sensor does not include an inlet configured to provide pressurized gas for the reference outlet and the measurement outlet.

44. A lithographic apparatus comprising:
an illumination system configured to condition a radiation beam;
a support constructed to support a patterning device, the patterning device being capable of imparting the radiation beam with a pattern in its cross-section to form a patterned radiation beam;
a substrate table constructed to hold a substrate;
a projection system configured to project the patterned radiation beam onto a target portion of the substrate; and
a height measurement apparatus comprising an array of differential pressure sensors wherein adjacent differential pressure sensors have a periodic spacing, each differential pressure sensor comprising:
a reference outlet and a measurement outlet, the reference outlet being at a predetermined distance from a reference surface;
an inlet configured to provide pressurized gas for the reference outlet and the measurement outlet;
a flexible membrane positioned such that a reference side of the flexible membrane is in fluid communication with the reference outlet and a measurement side of the flexible membrane is in fluid communication with the measurement outlet, the flexible membrane being configured to move when a pressure change occurs at the measurement outlet; and
a detector configured to monitor movement of the flexible membrane.

45. A height measurement method comprising:
providing an array of differential pressure sensors with a pressurized gas wherein adjacent differential pressure sensors have a periodic spacing, each differential pressure sensor comprising a flexible membrane configured to move when a pressure change occurs at a measurement outlet of the differential pressure sensor;
positioning a surface of a substrate proximate measurement outlets of the array of differential pressure sensors;
providing relative movement between the array of differential pressure sensors and the surface of the substrate;
sensing pressure changes during the relative movement by monitoring movement of the flexible membrane; and
analysing the sensed pressure changes to determine the height of the substrate.

46. A process of manufacturing a height measurement apparatus, the process comprising:
providing a detection device on a device layer of a first wafer;
providing a second wafer with an inlet, a reference channel and a reference outlet, the inlet, reference channel and reference outlet being in fluid communication with each other;
bonding the first wafer to the second wafer such that a continuous path exists from the inlet, through the reference channel, past the detection device and through the reference outlet;
thinning the first wafer from underneath the first wafer;
forming a flexible membrane from the first wafer such that the detection device is located on the flexible membrane;
providing a third wafer with a measurement outlet;
bonding the third wafer to the first wafer such that a measurement channel is defined by the third wafer and the first wafer, the measurement channel being in fluid communication with the inlet and the measurement outlet such that a continuous path exists from the inlet, through the measurement channel, past the flexible membrane and through the measurement outlet;
providing a fourth wafer with an inlet and a reference outlet channel; and
bonding the fourth wafer to the second wafer such that the inlet of the fourth wafer is aligned with the inlet of the second wafer, and the reference outlet channel is in fluid communication with the reference outlet.

47. The process of claim 46, wherein the second wafer is provided with a device chamber configured to accommodate monitoring electronics and/or optics.
